(19) United States
(12) Patent Application Publication
(10) Pub. No.: US 2010/0175614 A1
(43) Pub. Date: Jul. 15, 2010

(54) THERMALLY INSULATED CONFIGURATION AND METHOD FOR PRODUCING A BULK SIC CRYSTAL

(75) Inventor: Thomas Straubinger, Erlangen (DE)

Correspondence Address: LERNER GREENBERG STEMER LLP, P O BOX 2480, HOLLYWOOD, FL, 33022-2480, US

(73) Assignee: SICRYSTAL AG, Erlangen (DE)

(21) Appl. No.: 12/686,788

(22) Filed: Jan. 13, 2010

(30) Foreign Application Priority Data
Jan. 15, 2009 (DE) 10 2009 004 751.4

(51) Int. Cl. C30B 23/02

(52) U.S. Cl. 117/103; 117/200

(57) ABSTRACT

A configuration for producing a bulk SiC crystal includes a growing crucible having an electrically conductive crucible wall, an inductive heating device disposed outside the growing crucible for inductively coupling an electric current, which heats the growing crucible, into the crucible wall, and an insulation layer disposed between the crucible wall and the inductive heating device. The insulation layer is formed of a graphite insulation material having short carbon fibers with a fiber length in a range of between 1 mm and 10 mm and a fiber diameter in a range of between 0.1 mm and 1 mm. A method for producing a bulk SiC crystal is also provided.

### CROSS-REFERENCE TO RELATED APPLICATION

This application claims the priority, under 35 U.S.C. §119, of German Patent Application DE 10 2009 004 751.4, filed Jan. 15, 2009; the prior application is herewith incorporated by reference in its entirety.

### BACKGROUND OF THE INVENTION

1. Field of the Invention

The invention relates to a configuration for producing a bulk SiC crystal. The invention furthermore relates to a method for producing a bulk SiC crystal.

Due to its outstanding physical, chemical and electrical properties, semiconductor material silicon carbide (SiC) is also used inter alia as a substrate material for power electronic semiconductor components, for radiofrequency components and for special light-emitting semiconductor components. Bulk SiC crystals with pure and defect-free quality are required as a basis.

Bulk SiC crystals are generally produced through the use of physical vapor deposition, in particular through the use of a sublimation method. Temperatures of more than 2000° C. are required therefor. In order to ensure that the walls of the inductively heated inner growing crucible are not damaged under those conditions, it is generally clad with an insulation layer of porous graphite. Since the thermal insulation layer is electrically conductive, a current flows in the porous graphite of the thermal insulation layer due to the inductive heating, and as a result thereof the insulation layer becomes heated and worn. In the extreme case, it can even lead to cracks in the insulation layer and/or on the inner wall of the reactor, usually configured as a quartz glass tube, which contains the thermally clad growing crucible, or it can lead to a maximum permissible temperature being exceeded and therefore to damage or destruction thereof.

### SUMMARY OF THE INVENTION

It is accordingly an object of the invention to provide a thermally insulated configuration and a method for producing a bulk SiC crystal, which overcome the hereinafore-mentioned disadvantages of the heretofore-known configurations and methods of this general type and in which the thermally insulated configuration has a long service life and can also be used repeatedly.

With the foregoing and other objects in view there is provided, in accordance with the invention, a configuration for producing a bulk SiC crystal. The configuration comprises a growing crucible having an electrically conductive crucible wall, an inductive heating device disposed outside the growing crucible, for inductively coupling an electric current heating the growing crucible into the crucible wall, and an insulation layer disposed between the crucible wall and the inductive heating device, the insulation layer formed of a graphite insulation material having short carbon fibers with a fiber length in a range of between 1 mm and 10 mm and a fiber diameter in a range of between 0.1 mm and 1 mm.

The fiber length is, in particular, an average fiber length. Preferably, at least 90% of the carbon fibers have a length in the range, i.e. between 1 mm and 10 mm. The fiber diameter is likewise, in particular, an average fiber diameter, at least 90% of the carbon fibers again preferably having a diameter in the range, i.e. between 0.1 mm and 1 mm.

Due to the use of the graphite insulation material formed of short carbon fibers according to the invention, a continuous current path inside the thermal insulation layer is avoided. This reduces the electrical conductivity of the graphite insulation material used for the insulation layer, which is in particular porous and preferably has a lower density than the crucible material of the growing crucible, which preferably likewise is formed of graphite. With a reduced flow of current inside the thermal insulation layer, the number and intensity of the heat sources inside the insulation layer also decrease. The thermal stress on the insulation layer is consequently reduced, so that it has a longer service life and can be used more often.

Another advantage is that, due to the poorer electrical conductivity of the graphite insulation material being used, the inductive heating power is to a much greater extent delivered where it is required, i.e. in the crucible wall and no longer as previously to a certain extent also in the insulation layer. Heating the thermal insulation layer is undesirable and counterproductive. Use of the graphite insulation material formed of short carbon fibers is also to be regarded as positive with respect to the heating power required in order to heat the growing configuration. The power consumption is reduced.

Overall, the bulk SiC crystal can be produced very economically in this way.

In accordance with another feature of the invention, the graphite insulation material has an electrical conductivity in a range of between 100 Ω⁻¹m⁻¹ and 1000 Ω⁻¹m⁻¹. The electrical conductivity of dense graphite which is not according to the invention, on the other hand, is at least two orders of magnitude higher, i.e. about 10⁵ Ω⁻¹m⁻¹. The much lower electrical conductivity provided, in particular, in this case contributes decisively to the insulation layer which is not, or at least only to a much lesser extent, being heated directly by induced currents.

In accordance with a further feature of the invention, the graphite insulation material has a thermal conductivity in a range of between 0.1 Wm⁻¹K⁻¹ and 5 Wm⁻¹K⁻¹, in particular at a temperature of at least 2000° C. The thermal conductivity of dense graphite which is not according to the invention, on the other hand, is at least 5 times higher, i.e. about 25 Wm⁻¹K⁻¹. The much lower thermal conductivity which is provided, in particular, in this case contributes decisively to the growing crucible being thermally insulated well and losing as little as possible of the heat energy required for the crystal growth.

In accordance with an added feature of the invention, the short carbon fibers are disposed inside the graphite insulation material while being distributed in an unordered or random fashion. The suppression of the current flow and therefore of heat sources inside the insulation layer is already obtained with carbon fibers oriented in an unordered fashion, merely due to their short geometrical dimensions which prevent a continuous current path inside the thermal insulation layer. An insulation layer having unordered carbon fibers can be produced particularly simply and economically.

In accordance with an additional feature of the invention, at least 90% of the short carbon fibers are disposed inside the graphite insulation material while being distributed in an ordered fashion. In this way, a current flow induced by the heating device other than inside the insulation layer can be suppressed particularly efficiently.

In accordance with yet another feature of the invention, the insulation layer includes at least one part having a hollow cylindrical shape and a central longitudinal mid-axis. In particular, at least 90% of the short carbon fibers are aligned in the direction of the longitudinal mid-axis. According to a first alternative particular configuration, in particular at least 90% of the short carbon fibers are aligned perpendicularly to the longitudinal mid-axis and mutually parallel. According to a second alternative particular configuration, in particular at least 90% of the short carbon fibers are aligned perpendicularly to the longitudinal mid-axis and respectively in a radial direction of the hollow cylindrical shape. With each of these three configurations, the inductive ring currents preferentially induced by the heating coil inside the hollow cylindrical insulation layer are suppressed particularly well. The longitudinal fiber direction most suitable for carrying a current is in each case, for the majority of the carbon fibers, perpendicular to the potential flow direction of the induced ring currents, which are therefore suppressed very well.

In accordance with yet a further feature of the invention, the insulation layer is produced from a raw material in which at least 90% of the short carbon fibers are disposed with a uniform orientation. This leads to particularly low production costs for the insulation layer. A block of such a raw material may, for example, be produced by the short carbon fibers being substantially aligned uniformly with their longitudinal fiber direction in a vibrating screen with V-shaped indentations and laid on a support. This process is repeated several times with an offset until complete covering of the support is achieved. The fibers are subsequently compacted by pressing. This laying procedure is repeated several times. A block of the raw material is thereby gradually produced, with the microstructure thereof having a preferential direction of the short carbon fibers. A hollow cylindrical insulation layer with a uniform fiber alignment, parallel or perpendicular to the longitudinal mid-axis, can then be produced easily from this raw material block.

In accordance with yet an added feature of the invention, in an alternative configuration of a hollow cylindrical insulation layer, with the fiber direction extending perpendicularly to the longitudinal mid-axis and radially, the raw material is produced through the use of a somewhat modified method. The short carbon fibers aligned through the use of the vibrating screen are laid radially in a mold intended for this purpose.

In accordance with yet an additional feature of the invention, the growing crucible has an inner diameter of for example at least 50 mm, in particular at least 100 mm, and preferably at least 200 mm. Particularly large bulk SiC crystals can thereby be produced, in particular ones with a large cross-sectional diameter, and accordingly very large SiC substrates. The monocrystalline SiC substrates are obtained from the bulk SiC crystal by axially cutting or sawing them off successively as wafers perpendicularly to the growth direction. A main substrate surface of such a large SiC substrate has a substrate diameter of for example at least 50 mm, in particular at least 100 mm, and preferably at least 200 mm. The larger the main substrate surface is, the more efficiently the SiC substrate can be used further for the production of semiconductor components. This reduces the production costs for the semiconductor components. Due to the use of the graphite insulation material formed of short carbon fibers according to the invention, and the concomitant lower level of heating in the insulation volume, it is possible to provide an insulation layer which is thinner than before, particularly as seen in the radial direction. With the same reactor diameter, this therefore offers the possibility of using a larger inner growing crucible and consequently growing larger bulk SiC crystals.

In accordance with again another feature of the invention, the insulation layer has a layer thickness of at most 50 mm, in particular at most 30 mm. The radial wall thickness of conventional insulation layers is up to 100 mm, depending on the size of the bulk SiC crystal being grown. As explained above, using the graphite insulation material according to the invention makes it possible to reduce this insulation wall thickness. For a cross-sectional diameter of the bulk SiC crystal to be grown measuring about 50 mm, an insulation layer with a layer thickness of, in particular, only at most 30 mm is then entirely sufficient. For larger bulk SiC crystals with a cross-sectional diameter of about 100 mm or more, an insulation layer thickness of, in particular, only at most 50 mm is then entirely sufficient. One advantage of such thin insulation layers is inter alia also that it is possible to use smaller reactors and heating coils with a smaller coil diameter. In particular, the latter leads to improved coupling of the heating power into the growing crucible.

It is also an object of the invention to provide a method for producing a bulk SiC crystal, which allows favorable production of the bulk SiC crystal.

With the objects of the invention in view, there is also provided a method for producing a bulk SiC crystal. The method comprises generating an SiC growth gas phase in a crystal growth region of a growing crucible and growing the bulk SiC crystal by deposition from the SiC growth gas phase, inductively coupling an electric current into an electrically conductive crucible wall of the growing crucible by an inductive heating device disposed outside the growing crucible, for heating the growing crucible, and providing an insulation layer between the crucible wall and the inductive heating device, and forming the insulation layer of a graphite insulation material having short carbon fibers with a fiber length in a range of between 1 mm and 10 mm and a fiber diameter in a range of between 0.1 mm and 1 mm.

The method according to the invention and these and other configurations thereof have basically the same advantages as have already been described in connection with the configuration according to the invention and its corresponding variants.

Other features which are considered as characteristic for the invention are set forth in the appended claims.

Although the invention is illustrated and described herein as embodied in a thermally insulated configuration and a method for producing a bulk SiC crystal, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a fragmentary, diagrammatic, longitudinal-sectional view of an exemplary embodiment of a growing configuration for the production of a bulk SiC crystal with a thermally insulated growing crucible; and

FIGS. 2 to 4 are respective fragmentary, longitudinal-sectional and cross-sectional views of exemplary embodiments of thermal insulation layers for a growing crucible according to FIG. 1, made of a graphite insulation material having short carbon fibers respectively oriented in particular ways.

### DETAILED DESCRIPTION OF THE INVENTION

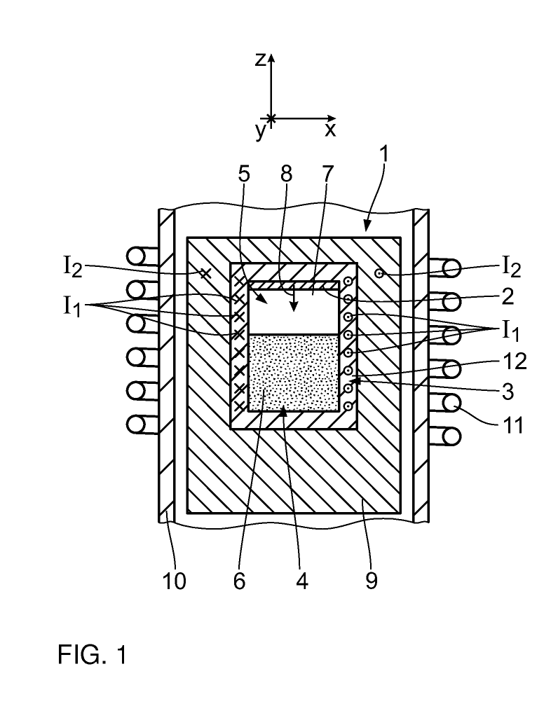

Referring now in detail to the figures of the drawings, in which parts which correspond to one another are provided with the same reference numerals, and first, particularly, to FIG. 1 thereof, there is seen an exemplary embodiment of a growing configuration 1 for the production of a bulk SiC crystal 2. The growing configuration 1 contains a growing crucible 3, which includes an SiC supply region 4 and a crystal growth region 5. The SiC supply region 4 contains, for example, powdered SiC source material 6, with which the SiC supply region 4 of the growing crucible 3 is filled as a prefabricated starting material before the start of the growing process.

In the crystal growth region 5, a seed crystal (not represented in detail) is applied on an inner wall of the growing crucible 3 lying opposite the SiC supply region 4. The bulk SiC crystal 2 to be produced grows from this seed crystal through the use of deposition from an SiC growth phase 7 which is formed in the crystal growth region 5.

The SiC growth phase 7 is obtained by sublimation of the SiC source material 6 and transport of sublimed gaseous parts of the SiC source material 6 in the direction of a growth surface of the bulk SiC crystal 2. The SiC growth phase 7 contains at least gas constituents in the form of Si, Si₂C and SiC₂. The transport of the SiC source material 6 to the growth surface takes place along a temperature gradient. The temperature inside the growing crucible 3 decreases toward the growing bulk SiC crystal 2. The bulk SiC crystal 2 grows in a growth direction 8, which in the exemplary embodiment shown in FIG. 1 is oriented from the top downward, i.e. from the upper wall of the growing crucible 3 to the SiC supply region 4 disposed underneath.

A thermal insulation layer 9 is disposed around the growing crucible 3. The thermally insulated growing crucible 3 is placed inside a tubular container 10, which in the exemplary embodiment is configured as a quartz glass tube and forms an autoclave or reactor. In order to heat the growing crucible 3, an inductive heating device in the form of a heating coil 11 is disposed around the container 10. The heating coil 11 couples an electric current I₁ inductively into an electrically conductive crucible wall 12 of the growing crucible 3. The current I₁ flows substantially as a circular current in the circumferential direction inside the hollow cylindrical crucible wall 12. The relative positions of the heating coil 11 and the growing crucible 3 can be varied in the growth direction 8, particularly in order to set the temperature or the temperature profile inside the growing crucible 3, and if need be to also change it. The growing crucible 3 is heated to temperatures of more than 2000° C. through the use of the heating coil 11.

In the exemplary embodiment according to FIG. 1, the growing crucible 3 is formed entirely of an electrically and thermally conductive graphite crucible material. The graphite used as the crucible material furthermore has a density of at least 90% of a theoretical maximum density of 3.2 g/cm³. It is therefore dense graphite.

The thermal insulation layer 9 is formed of a graphite insulation material having short carbon fibers, at least 90% of which have a length of between 1 mm and 10 mm and a diameter of between 0.1 mm and 1 mm. This graphite insulation material is less dense than the graphite crucible material and, in particular, has much lower electrical and thermal conductivities. The electrical conductivity is, for example, about 500 Ω⁻¹m⁻¹ and the thermal conductivity about 1 Wm^{'11}K⁻¹. The much lower electrical conductivity as compared with the graphite crucible material is due to the short carbon fibers of the insulation layer 9. In the exemplary embodiment according to FIG. 1, these carbon fibers are disposed in an unordered fashion inside the graphite insulation material used for the thermal insulation layer 9. Due to the short carbon fibers, there is no continuous current path inside the thermal insulation layer 9, so that electric currents 1₂ which would otherwise be induced there are virtually entirely suppressed. This is advantageous since no current-related heat sources are then formed inside the thermal insulation layer 9. The thermal insulation layer 9 can consequently be configured with a very thin layer thickness (=wall thickness) of, for example, only 30 mm or 50 mm, without an excessive temperature being established on the inner side of the tubular container 10.

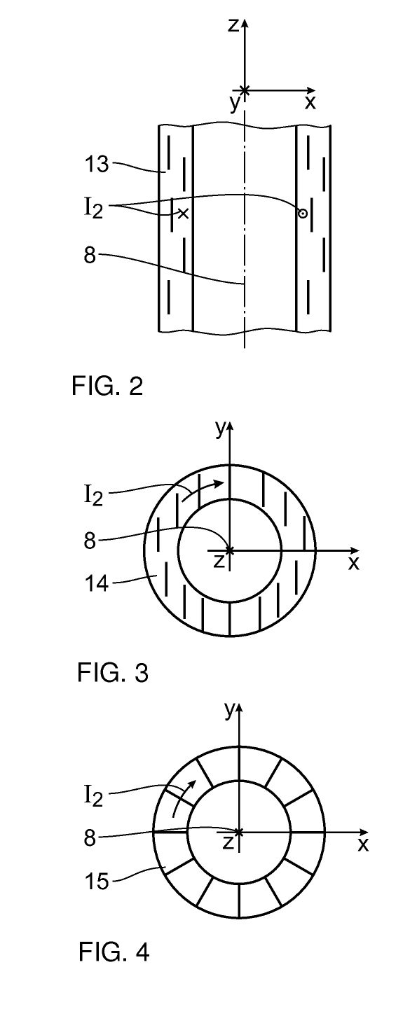

FIGS. 2 to 4 represent alternative exemplary embodiments of hollow cylindrical thermal insulation layers 13, 14 and 15, which are likewise produced from a graphite insulation material having short carbon fibers. This again offers the advantageous low electrical and thermal conductivities already described in connection with the exemplary embodiment according to FIG. 1. Each of the insulation layers 13 to 15 can be used in a growing configuration comparable with that according to FIG. 1, instead of the thermal insulation layer 9 provided therein.

Like FIG. 1, FIG. 2 represents a longitudinal section in the direction of a central longitudinal mid-axis of the hollow cylindrical insulation layer 13, through a portion thereof. The central longitudinal mid-axis corresponds substantially to the axis of the growth direction 8. FIGS. 3 and 4, on the other hand, show cross sections perpendicular to the central longitudinal mid-axis through the insulation layers 14 and 15.

In contrast to the thermal insulation layer 9, in which the carbon fibers are provided in an unordered fashion inside the graphite insulation material, deliberate alignment of the short carbon fibers is provided in the thermal insulation layers 13 to 15.

In the thermal insulation layer 13 according to FIG. 2, at least 90% of the short carbon fibers are disposed with their longitudinal fiber direction in the direction of the central longitudinal mid-axis. For better clarity, a Cartesian coordinate system with the conventional orthogonal axes x, y and z is also indicated in FIGS. 1 to 4. The central longitudinal mid-axis and the growth direction 8 are oriented parallel to the z axis.

In the thermal insulation layer 14 according to FIG. 3, at least 90% of the short carbon fibers are disposed with their longitudinal fiber direction oriented perpendicularly to the central longitudinal mid-axis. As in the insulation layer 13, however, the short carbon fibers are likewise substantially oriented mutually parallel. The alignment factor of the short carbon fibers is respectively 90%.

In the thermal insulation layer 14 according to FIG. 4, at least 90% of the short carbon fibers are disposed with their longitudinal fiber direction again oriented perpendicularly to the central longitudinal mid-axis, but not mutually parallel. Rather, they are oriented radially within the xy plane in relation to the z axis (=central longitudinal mid-axis). This radial orientation is schematically indicated in the representation according to FIG. 4, like the parallel configuration in the exemplary embodiments according to FIGS. 2 and 3.

In the insulation layers 13 to 15, the short carbon fibers are thus disposed in such a way that a considerable proportion of them come to lie with their longitudinal fiber direction perpendicular to the current flow direction, extending in the circumferential direction, of a current I₂ induced by the heating coil 11. Such a current I₂ is not therefore formed inside the insulation layers 13 to 15, or not to a significant extent.

For illustration, the basic current flow direction of the substantially suppressed induced electric currents I₂ is also indicated inside the insulation layer 9, 13, 14 or 15 in FIGS. 1 to 4. Conversely, the electric currents I₁ which are likewise indicated as well in the representation according to FIG. 1 and which are induced in the crucible wall 12 in order to heat the growing crucible 3, are not suppressed.

1. A configuration for producing a bulk SiC crystal, the configuration comprising:
a) a growing crucible having an electrically conductive crucible wall;
b) an inductive heating device disposed outside said growing crucible, for inductively coupling an electric current heating said growing crucible into said crucible wall; and
c) an insulation layer disposed between said crucible wall and said inductive heating device, said insulation layer formed of a graphite insulation material having short carbon fibers with a fiber length in a range of between 1 mm and 10 mm and a fiber diameter in a range of between 0.1 mm and 1 mm.

2. The configuration according to claim 1, wherein said graphite insulation material has an electrical conductivity in a range of between 100 Ω⁻¹m⁻¹ and 1000 Ω⁻¹m⁻¹.

3. The configuration according to claim 1, wherein said graphite insulation material has a thermal conductivity in a range of between 0.1 Wm⁻¹K⁻¹ and 5 Wm⁻¹ K⁻¹.

4. The configuration according to claim 1, wherein said short carbon fibers are distributed in an unordered fashion inside said graphite insulation material.

5. The configuration according to claim 1, wherein at least 90% of said short carbon fibers are distributed in an ordered fashion inside said graphite insulation material.

6. The configuration according to claim 5, wherein said insulation layer includes at least one part having a hollow cylindrical shape and a central longitudinal mid-axis, and at least 90% of said short carbon fibers are aligned in direction of said central longitudinal mid-axis.

7. The configuration according to claim 5, wherein said insulation layer includes at least one part having a hollow cylindrical shape and a central longitudinal mid-axis, and at least 90% of said short carbon fibers are aligned perpendicularly to said central longitudinal mid-axis and are mutually parallel.

8. The configuration according to claim 5, wherein said insulation layer includes at least one part having a hollow cylindrical shape and a central longitudinal mid-axis, and at least 90% of said short carbon fibers are aligned perpendicularly to said central longitudinal mid-axis and are aligned in radial direction of said hollow cylindrical shape.

9. The configuration according to claim 5, wherein said insulation layer is formed of a raw material in which at least 90% of said short carbon fibers are disposed with a uniform orientation.

10. The configuration according to claim 1, wherein said growing crucible has an inner diameter of at least 100 mm.

11. The configuration according to claim 1, wherein said insulation layer has a layer thickness of at most 50 mm.

12. The configuration according to claim 1, wherein said insulation layer has a layer thickness of at most 30 mm.

13. A method for producing a bulk SiC crystal, the method comprising the following steps:
a) generating an SiC growth gas phase in a crystal growth region of a growing crucible and growing the bulk SiC crystal by deposition from the SiC growth gas phase;
b) inductively coupling an electric current into an electrically conductive crucible wall of the growing crucible by an inductive heating device disposed outside the growing crucible, for heating the growing crucible; and
c) providing an insulation layer between the crucible wall and the inductive heating device, and forming the insulation layer of a graphite insulation material having short carbon fibers with a fiber length in a range of between 1 mm and 10 mm and a fiber diameter in a range of between 0.1 mm and 1 mm.

14. The method according to claim 13, wherein the graphite insulation material is a graphite having an electrical conductivity in a range of between 100 Ω⁻¹m⁻¹ and 1000 Ω⁻¹m⁻¹.

15. The method according to claim 13, wherein the graphite insulation material is a graphite having a thermal conductivity in a range of between 0.1 Wm⁻¹K⁻¹ and 5 Wm⁻¹K⁻¹.

16. The method according to claim 13, wherein the graphite insulation material is a graphite in which the short carbon fibers are distributed in an unordered or ordered fashion inside the graphite insulation material.

17. The method according to claim 13, wherein the growing crucible has an inner diameter of at least 100 mm.

18. The method according to claim 13, wherein the insulation layer has a layer thickness of at most 50 mm.

19. The method according to claim 13, wherein the insulation layer has a layer thickness of at most 30 mm.
